(19) United States
(12) Patent Application Publication
(10) Pub. No.: US 2003/0160322 A1
(43) Pub. Date: Aug. 28, 2003

(54) Monolithic microwave integrated circuit package having thermal via

(76) Inventors: Tsung-Ying Hsieh, Hsinchu (TW); Chin-Lien Hsu, Hsinchu (TW); Wen-Rui Hsu, Taoyuan (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/064,240

(22) Filed: Jun. 25, 2002

(30) Foreign Application Priority Data
Feb. 27, 2002 (TW) 91103521

(51) Int. Cl. H01L 23/34

(52) U.S. Cl. 257/728

(57) ABSTRACT

A monolithic microwave integrated circuit chip package having thermal vias therein comprising a package substrate, a monolithic microwave integrated circuit chip, a plurality of bumps and a plastic package body. The package channels the ground-signal-ground or ground-signal bonding pad arrangement on the monolithic microwave integrated circuit chip to points outside the package so that the monolithic microwave integrated circuit chip inside the package may operate in the optimal conditions.

### CROSS REFERENCE TO RELATED APPLICATIONS

This application claims the priority benefit of Taiwan application serial no. 91103521, filed Feb. 27, 2002.

### BACKGROUND OF INVENTION

1. Field of Invention

The present invention relates to a monolithic microwave integrated circuit (MMIC) package. More particularly, the present invention relates to a monolithic microwave integrated circuit package having thermal vias therein.

2. Description of Related Art

Microwave/millimeter wave integrated circuit has an operating frequency between 3˜30 GHz and 30˜300 GHz. In general, functions and applications of microwave/millimeter wave integrated circuits are limited by the package structures. Hence, the packaging method is important for many aspects of a monolithic microwave integrated circuit chip (MMIC) package. Preferably, a MMIC package has a high operating frequency, a low parasitic inductance and capacitance, a high heat dissipating capacity, a small package volume, a low production cost and a capacity for automated mass production.

FIG. 1 is a cross-sectional view of a conventional monolithic microwave integrated circuit package. The MMIC is packaged in the so-called “small outline integrated circuit” (SOIC) format. As shown in FIG. 1, a chip 104 is adhered to the paddle 106 of a lead frame 102 by a surface mounting technique. A wire bonding operation 108 is carried out. Thereafter, the wires are fixed in position using glue material 110. An injection molding process is conducted using plastic material 112 to form a package. The plastic material 112 prevents moisture, dust and contaminants from reaching the chip that might result in some changes to electrical properties.

FIG. 2 is a cross-sectional view of another conventional monolithic microwave integrated circuit package. Because the lead frame in FIG. 1 might lead to significant increase in parasitic capacitance and inductance, the monolithic microwave integrated circuit package in FIG. 2 uses an insulating substrate 202 to support a monolithic microwave integrated circuit chip 204. The insulating substrate 202 has an upper surface and a lower surface. Both the upper and lower surface have a plurality of contact points 202a and 202b. Electrical connection between the upper contact points 202a and the lower contact points 202b is achieved through vias 202c. The monolithic microwave integrated circuit chip 204 is attached to the insulating substrate 202. A wire-bonding operation is carried out to connect contact points 203 on the monolithic microwave integrated circuit chip 204 with the contact points 202a on the insulating substrate 202. Glue material 208 is applied to encapsulate the monolithic microwave integrated circuit chip 204 and the wires 206. Finally, an injection molding is conducted to form a plastic package body 210.

The bonding wires inside a conventional monolithic microwave integrated circuit package are a source of parasitic capacitance and parasitic inductance. Such parasitic inductance and capacitance often leads to significant reactance mismatch and self-resonance that may have considerable effect on high frequency response.

In addition, a gallium-arsenic chip is often used inside a conventional monolithic microwave integrated circuit package. Since gallium-arsenic is a poor thermal conductor, the monolithic microwave integrated circuit is frequently overheated leading to a shorter working life.

### SUMMARY OF INVENTION

Accordingly, one object of the present invention is to provide a monolithic microwave integrated circuit package having thermal vias therein capable of minimizing reactance mismatch and self-resonance resulting from parasitic capacitance and inductance.

A second object of this invention is to provide a monolithic microwave integrated circuit package having thermal vias therein that uses flip-chip joining technique to replace a conventional wire-bonding step so that fabrication can be automated and produced en-mass.

A third object of this invention is to provide a monolithic microwave integrated circuit package having thermal vias therein for increasing the dissipation of heat from the monolithic microwave integrated circuit.

A fourth object of this invention is to provide a monolithic microwave integrated circuit package having thermal vias therein capable of improving electrical properties through bonding pads having a ground-signal-ground (G-S-G) sequence or ground-signal (G-S) sequence on the monolithic microwave integrated circuit chip directly to the exterior of the package.

To achieve these and other advantages and in accordance with the purpose of the invention, as embodied and broadly described herein, the invention provides a monolithic microwave integrated circuit package having thermal vias therein. The package mainly comprises a package substrate, a monolithic microwave integrated circuit chip, a plurality of bumps and a plastic package body.

The package substrate includes a first dielectric layer, a plurality of first conductive vias, a plurality of thermal vias, a first patterned wiring layer, a second patterned wiring layer, a second dielectric layer and a plurality of second conductive vias. The first dielectric layer has a first surface and a second surface. The first conductive vias and the thermal vias are formed inside the first dielectric layer. The first patterned wiring layer is formed on the first surface of the first dielectric layer. The second patterned wiring layer is formed on the second surface of the first dielectric layer. The second dielectric layer is formed over the first dielectric layer. The second conductive vias are formed inside the second dielectric layer. In addition, the second conductive vias and the first conductive vias are electrically connected through the first patterned wiring layer.

The monolithic microwave integrated circuit is placed over the package substrate. The monolithic microwave integrated circuit has a plurality of first bonding pads. The first bonding pads are sequenced in a ground-signal-ground pattern having, for example, a signal input pad and two adjacent first ground pads and a signal output pad and two adjacent ground pads.

In addition, the first bonding pads may also be sequenced in a ground-signal pattern having a signal input pad and an adjacent first ground pad and a signal output pad and an adjacent second ground pad.

The monolithic microwave integrated circuit chip may have a plurality of first bonding pads, second bonding pads that includes at least a third ground pad and at least a dummy pad. Furthermore, the second bonding pads may also include at least one power pad. The power pad is connected to a DC power, for example.

The bumps are placed between the bonding pads and the second conductive vias for connecting the bonding pads and the second conductive vias electrically. The plastic package body is formed over the package substrate such that the monolithic microwave integrated circuit chip is attached solidly over the package substrate.

The monolithic microwave integrated circuit has an active region and the thermal vias inside the first dielectric layer are located under the active region. The second surface of the first dielectric layer has a second patterned wiring layer. The second patterned wiring layer enables the package body to connect with other substrate layers through surface mounting technologies.

This invention also provides an alternative monolithic microwave integrated circuit package having thermal vias therein. The package mainly comprises of a package substrate, a monolithic microwave integrated circuit chip, a plurality of bumps and a plastic package body.

The package substrate includes a plurality of dielectric layers, a plurality of conductive vias, a plurality of patterned wiring layers and a plurality of thermal vias. The conductive vias are formed inside various dielectric layers and the patterned wiring layers are formed between various dielectric layers. The conductive vias and the patterned wiring layers together may constitute a fan-out wiring structure. The thermal vias are formed inside the dielectric layers.

The monolithic microwave integrated circuit is placed over the package substrate. The monolithic microwave integrated circuit has a plurality of bonding pads. The bonding pads are sequenced in a ground-signal-ground pattern or a signal-ground pattern. The bumps are placed between the bonding pads and the package substrate for connecting the bonding pads and the conductive vias electrically. The plastic package body is formed over the package substrate such that the monolithic microwave integrated circuit chip is attached solidly over the package substrate.

The monolithic microwave integrated circuit has an active region and the thermal vias inside the first dielectric layer are located under the active region.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a cross-sectional view of a conventional monolithic microwave integrated circuit package;

FIG. 2 is a cross-sectional view of another conventional monolithic microwave integrated circuit package;

FIGS. 3 and 4 are top views of two monolithic microwave integrated circuit chips according to one preferred embodiment of this invention;

FIG. 5 is a cross-sectional view of a package substrate according to one preferred embodiment of this invention;

FIGS. 6A, 6B and 6C are diagrams showing various layers inside a package substrate according to one preferred embodiment of this invention; and

FIG. 7 is a cross-sectional diagram showing a monolithic microwave integrated circuit chip package with internal thermal vias fabricated according to the preferred embodiment of this invention.

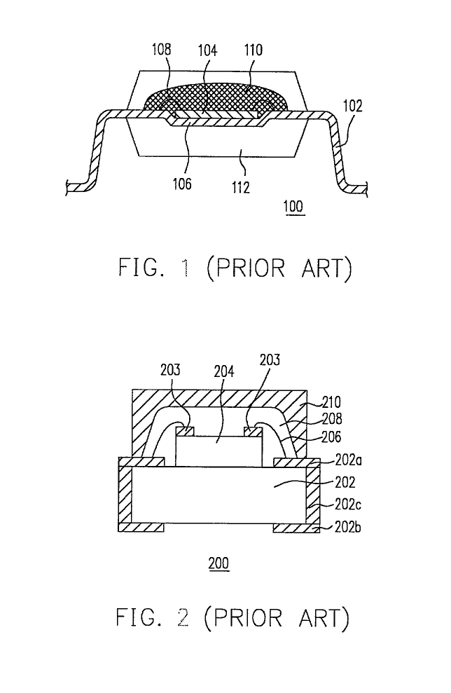

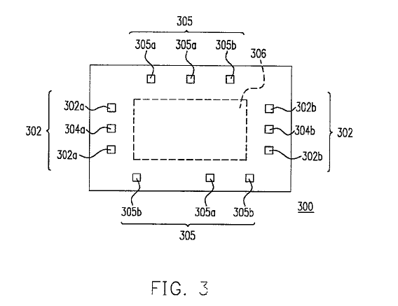

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

In general, high power flip-chip monolithic microwave integrated circuit packages can be classified according to the power rating. A package is considered a low power package if the power required is below 1 mW while a package is considered a high power package if the power required is above 1 mW. The monolithic microwave integrated circuit inside a high power package generates more heat compared with a low power package. Hence, a high power package needs to have additional cooling structures for increasing reliability. The package according to this invention is specially designed to remove as much heat from the high power packages as possible.

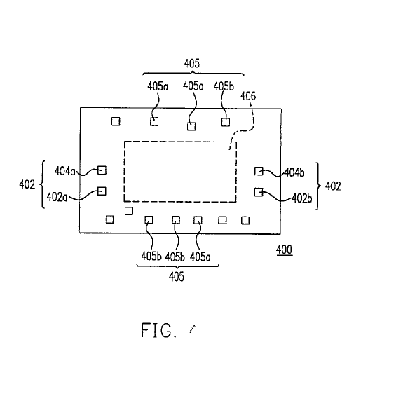

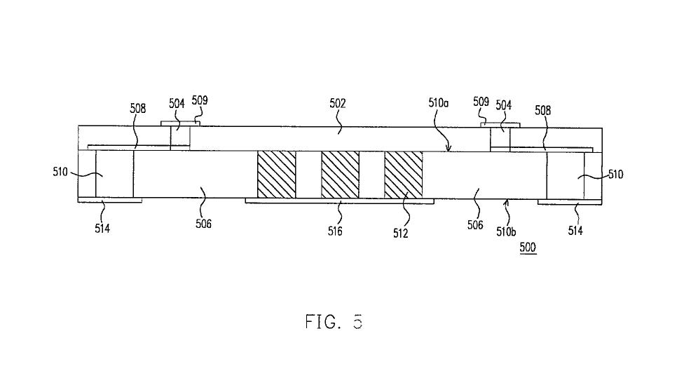

FIGS. 3 and 4 are top views of two monolithic microwave integrated circuit chips according to one preferred embodiment of this invention. In FIG. 3, a monolithic microwave integrated circuit chip 300 having an active region 306, a plurality of first bonding pads 302 and a plurality of second bonding pads 305 thereon is provided. The set of first bonding pads 302 includes a plurality of first ground pads 302a, a plurality of second ground pads 302b, a signal input pad 304a and a signal output pad 304b. The set of second bonding pads 305 includes at least a third ground pad 305a and at least a dummy pad 305b. The set of second bonding pads may also include a power pad. The power pad may connect with a DC power directly, for example. In addition, the first ground pads 302a, the second ground pads 302b, the signal input pads 304a and the signal output pads 304b are positioned around the active region 306.

The signal input pads 304a are radio frequency signal input terminal (RF-in) and the signal output pads 304b are radio frequency signal output terminal (RF-out), for example. Each side of the signal input pad 304a has a first ground pad 302a. Hence, a ground-signal-ground (G-S-G) pad sequence is formed. Similarly, each side of the signal output pad 304b has a second ground pad 302b. Hence, a ground-signal-ground (G-S-G) pad sequence is formed. The ground-signal-ground pattern formed by the signal input pad 304a and the adjacent first ground pads 302a constitute a coplanar wave-guide. Similarly, the ground-signal-ground pattern formed by the signal output pad 304b and the adjacent second ground pads 302b constitute a coplanar wave-guide.

In FIG. 4, a monolithic microwave integrated circuit chip 400 having an active region 406, a plurality of first bonding pads 402 and a plurality of second bonding pads 405 thereon is provided. The set of first bonding pads 402 includes a plurality of first ground pads 402a, a plurality of second ground pads 402b, a signal input pad 404a and a signal output pad 404b. The set of second bonding pads 405 includes at least a third ground pad 405a and at least a dummy pad 405b. The set of second bonding pads may also include a power pad. The power pad may connect with a DC power directly, for example. In addition, the first ground pads 402a, the second ground pads 402b, the signal input pads 404a and the signal output pads 404b are positioned around the active region 406.

The signal input pads 404a are radio frequency signal input terminal (RF-in) and the signal output pads 404b are radio frequency signal output terminal (RF-out), for example. One side of the signal input pad 404a has a first ground pad 402a. Hence, a ground-signal (G-S) pad sequence is formed. Similarly, one side of the signal output pad 404b has a second ground pad 402b. Hence, a ground-signal (G-S) pad sequence is formed.

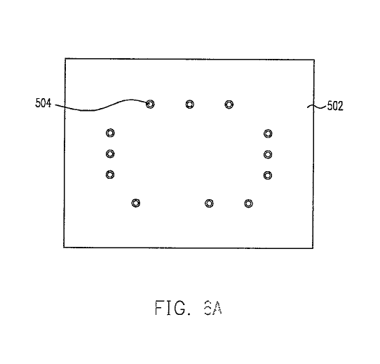

FIG. 5 is a cross-sectional view of a package substrate according to one preferred embodiment of this invention. As shown in FIG. 5, the package substrate 500 comprises a first dielectric layer 506, a plurality of first conductive vias 510, a plurality of thermal vias 512, a first patterned wiring layer 508, a second dielectric layer 502, a plurality of second conductive vias 504 and a second patterned wiring layer 514 and 516.

The first conductive vias 510 and the thermal vias 512 are formed inside the first dielectric layer 506. The first conductive vias 510 are formed closer to the outer edge of the first dielectric layer 506 and the thermal vias 512 are formed closer to the central region of the first dielectric layer 506.

The first dielectric layer 506 has a first surface 510a and a second surface 510b. The first patterned wiring layer 508 is formed on the first surface 510a of the first dielectric layer 506 and the second patterned wiring layer 514, 516 is formed on the second surface 510b of the first dielectric layer 506. The ends of the first conductive vias 510 exposed to the first surface 510a are electrically connected to the first patterned wiring layer 508. Similarly, the ends of the first conductive vias 510 exposed to the second surface 510b are electrically connected to the second patterned wiring layer 514. The ends of the thermal vias 512 exposed to the second surface 510b are electrically connected to the second patterned wiring layer 516.

The first patterned wiring layer 508 is also attached to a second dielectric layer 502. The second dielectric layer 502 has a plurality of second conductive vias 504. One end of the second conductive vias 504 is electrically connected to the first patterned wiring layer 508. Hence, the second conductive vias 504 connect electrically with the first conductive vias 510 through the first patterned wiring layer 508. Furthermore, connecting pads 509 for connecting with other integrated circuit chips may form over the other end of second conductive vias 504.

In this embodiment, the package substrate 500 has two layers. However, the number of layers constituting a package substrate may be more. Anyone familiar with integrated circuit fabrication may notice that the package substrate can be constructed using a number of conductive via studded dielectric layers and patterned wiring layers stacked alternately over each other.

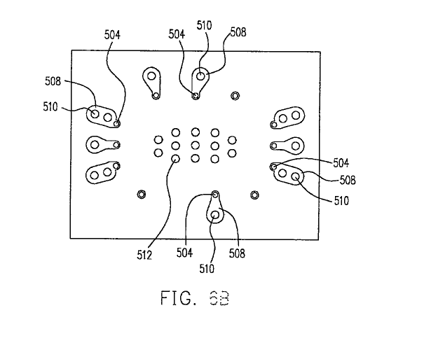

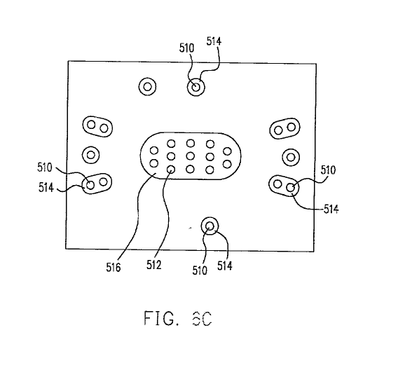

FIGS. 6A, 6B and 6C are diagrams showing various layers inside a package substrate according to one preferred embodiment of this invention. FIG. 6A is a top view of the package substrate 500. As shown in FIG. 6A, the second conductive vias 504 are formed in various places in the second dielectric layer 502. The second conductive vias 504 are located in positions corresponding to the first ground pads 302a, the second ground pads 302b, signal input pads 304a and signal output pads 304b of the monolithic microwave integrated circuit chip 300 (FIG. 3).

FIG. 6B is a top view showing the layout of the first patterned wiring layer 508. The purpose of having the first patterned wiring layer 508 is to connect the second conductive vias 504 and the first conductive vias 510 together electrically. Note that the thermal vias 512 within the first dielectric layer 506 are distributed mainly in the central region of the package substrate 500.

FIG. 6C is a bottom view of the package substrate 500. The first conductive vias 510 within the first dielectric layer 506 connect electrically with external contacts through the second patterned wiring layer 514. Similarly, the thermal vias 512 within the first dielectric layer 506 connect electrically with external contacts through the second patterned wiring layer 516.

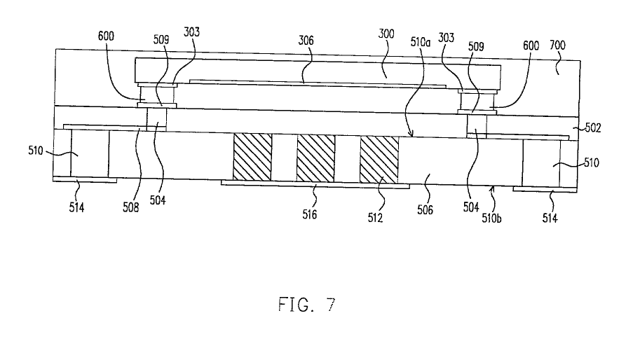

FIG. 7 is a cross-sectional diagram showing a monolithic microwave integrated circuit chip package with internal thermal vias fabricated according to the preferred embodiment of this invention. As shown in FIG. 7, the monolithic microwave integrated circuit chip package mainly comprises of a package substrate 500, a monolithic microwave integrated circuit chip 300, a plurality of bumps 600 and a plastic package body 700.

The monolithic microwave integrated circuit chip 300 is electrically connected to the connecting pads 509 on the package substrate 500 through the bumps 600 in a flip-chip assembling method. Since the monolithic microwave integrated circuit chip 300 and the package substrate 500 are electrically connected by a flip-chip method, the active region 306 of the monolithic microwave integrated circuit chip 300 faces the package substrate 500.

Contacts on the monolithic microwave integrated circuit chip 300 are fanned-out to external contacts on the plastic package body through the bumps 600 and the package substrate 500. Signals from the chip 300 are capable of reaching the external contacts after passing through an intricate structure inside the package substrate 500 including the first conductive vias 510, the first patterned wiring layer 508, the second conductive vias 504, the connecting pads 509 and the second patterned wiring layers 514 and 516.

The bumps 600 are positioned between the package substrate 500 and the monolithic microwave integrated circuit chip 300. The bumps 600 may be fabricated on top of the connecting pads 509 of the package substrate 500 or on the contacts on the monolithic microwave integrated circuit chip 300. If the bumps 600 are formed over the monolithic microwave integrated circuit 300, an underball metallic (UBM) layer 303 is frequently formed to increase package reliability. Since the bumps 600 are formed by a conventional method, detailed description is omitted.

In general, the monolithic microwave integrated circuit chip 300 and the package substrate 500 are made from different materials. Hence, there may be a mismatch in their respective coefficient of thermal expansion (CTE). The difference in CTE may lead to stress in the bumps 600 while the package is operating. To minimize this stress, plastic material is injected into a mold housing the monolithic microwave integrated circuit chip 300 and the package substrate 500. Ultimately, the monolithic microwave integrated circuit chip 300 and the package substrate 500 are encapsulated to form a plastic package body 700.

The plastic package body 700 not only protects the monolithic microwave integrated circuit chip 300 against shock, the plastic material between the monolithic microwave integrated circuit chip 300 and the package substrate 500 cushions the bumps 600 against thermal stress. Hence, the monolithic microwave integrated circuit chip package can have greater reliability during operation.

In conclusion, major advantages of this invention include:

1. The monolithic microwave integrated circuit chip package has thermal vias for conducting heat away from the chip package during operation.

2. The monolithic microwave integrated circuit chip package has a package substrate full of internal connecting structures for fanning out the contacts on the chip to external points so that overall electrical properties of the package are improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A monolithic microwave integrated circuit chip package having thermal vias therein, comprising:
a monolithic microwave integrated circuit chip, wherein the monolithic microwave integrated circuit chip has a plurality of first bonding pads arranged in a ground-signal-ground pattern and second bonding pads;
a package substrate for supporting the monolithic microwave integrated circuit chip, having a first dielectric layer, a plurality of first conductive vias, a plurality of thermal vias, a first patterned wiring layer, a second dielectric layer and a plurality of second conductive vias, wherein the first dielectric layer has a first surface and a second surface, the first conductive vias and the thermal vias are formed within the first dielectric layer, the first patterned wiring layer is formed on the first surface, the second dielectric layer is formed over the first dielectric layer, the second conductive vias are formed within the second dielectric layer, and the second conductive vias correspond in position to the first bonding pads and the second bonding pads so that signals in the monolithic microwave integrated circuit chip are directly channeled out;
a plurality of bumps formed between the monolithic microwave integrated circuit chip and the package substrate for electrically connecting the monolithic microwave integrated circuit chip and the package substrate together; and
a plastic package body encapsulating and fixing the monolithic microwave integrated circuit chip over the package substrate.

2. The package of claim 1, wherein the first bonding pads includes:
a signal input pad;
a pair of first ground pads on each side of the signal input pad;
a signal output pad; and
a pair of second ground pads on each side of the signal output pad.

3. The package of claim 1, wherein the second bonding pad at least includes a power pad.

4. The package of claim 3, wherein the second bonding pad at least includes a third ground pad.

5. The package of claim 4, wherein the second bonding pad at least includes a dummy pad.

6. The package of claim 1, wherein the monolithic microwave integrated circuit has an active region.

7. The package of claim 6, wherein the thermal vias within the first dielectric layer are formed underneath the active region.

8. The package of claim 1, wherein the second surface of the first dielectric layer has a second patterned wiring layer thereon.

9. The package of claim 1, wherein each second conductive via has a connecting pad thereon.

10. A monolithic microwave integrated circuit chip package having thermal vias therein, comprising:
a monolithic microwave integrated circuit chip, wherein the monolithic microwave integrated circuit chip has a plurality of first bonding pads arranged in a ground-signal pattern and second bonding pads;
a package substrate for supporting the monolithic microwave integrated circuit chip, having a first dielectric layer, a plurality of first conductive vias, a plurality of thermal vias, a first patterned wiring layer, a second dielectric layer and a plurality of second conductive vias, wherein the first dielectric layer has a first surface and a second surface, the first conductive vias and the thermal vias are formed within the first dielectric layer, the first patterned wiring layer is formed on the first surface, the second dielectric layer is formed over the first dielectric layer, the second conductive vias are formed within the second dielectric layer, and the second conductive vias correspond in position to the first bonding pads and the second bonding pads so that signals in the monolithic microwave integrated circuit chip are directly channeled out;
a plurality of bumps formed between the monolithic microwave integrated circuit chip and the package substrate for electrically connecting the monolithic microwave integrated circuit chip and the package substrate together; and
a plastic package body encapsulating and fixing the monolithic microwave integrated circuit chip over the package substrate.

11. The package of claim 10, wherein the first bonding pad includes:
a signal input pad;
a first ground pad on one side of the signal input pad;
a signal output pad; and
a second ground pad on one side of the signal output pad.

12. The package of claim 10, wherein the second bonding pad at least includes a power pad.

13. The package of claim 12, wherein the second bonding pad at least includes a third ground pad.

14. The package of claim 13, wherein the second bonding pad at least includes a dummy pad.

15. The package of claim 10, wherein the monolithic microwave integrated circuit has an active region.

16. The package of claim 15, wherein the thermal vias within the first dielectric layer are formed underneath the active region.

17. The package of claim 10, wherein the second surface of the first dielectric layer has a second patterned wiring layer thereon.

18. The package of claim 10, wherein each second conductive via has a connecting pad thereon.

19. A monolithic microwave integrated circuit chip package having thermal vias therein, comprising:
a monolithic microwave integrated circuit chip, wherein the monolithic microwave integrated circuit chip has a plurality of first bonding pads arranged in a ground-signal pattern and second bonding pads;
a package substrate having a plurality of dielectric layers, a plurality of conductive vias, a plurality of patterned wiring layers and a plurality of thermal vias, wherein the conductive vias are formed within the dielectric layers, the patterned wiring layers are between the dielectric layers, the conductive vias and the patterned wiring layers together constitute a multi-layered wiring structure, the thermal vias are formed within the dielectric layer, and the conductive vias are used for channeling signals from the monolithic microwave integrated circuit chip out of the package;
a plurality of bumps formed between the monolithic microwave integrated circuit chip and the package substrate for electrically connecting the monolithic microwave integrated circuit chip and the package substrate together; and
a plastic package body encapsulating and fixing the monolithic microwave integrated circuit chip over the package substrate.

20. The package of claim 19, wherein the first bonding pads on the monolithic microwave integrated circuit chip are arranged to form a ground-signal-ground pattern.

21. The package of claim 20, wherein the first bonding pads includes:
a signal input pad;
a pair of first ground pads on each side of the signal input pad;
a signal output pad; and
a pair of second ground pads on each side of the signal output pad.

22. The package of claim 19, wherein the first bonding pads on the monolithic microwave integrated circuit chip are arranged to form a ground-signal pattern.

23. The package of claim 22, wherein the first bonding pad includes:
a signal input pad;
a first ground pad on one side of the signal input pad;
a signal output pad; and
a second ground pad on one side of the signal output pad.

24. The package of claim 19, wherein the second bonding pad at least includes a power pad.

25. The package of claim 24, wherein the second bonding pad at least includes a third ground pad.

26. The package of claim 25, wherein the second bonding pad at least includes a dummy pad.

27. The package of claim 19, wherein the monolithic microwave integrated circuit has an active region.

28. The package of claim 27, wherein the thermal vias within the first dielectric layer are formed underneath the active region.
